(19) United States
(12) Patent Application Publication
(10) Pub. No.: US 2005/0241851 A1
(43) Pub. Date: Nov. 3, 2005

(54) PIN GRID ARRAY PACKAGE CARRIER AND PROCESS OF MOUNTING PASSIVE COMPONENT THEREON

(76) Inventor: CHIH-AN YANG, TAIPEI HSIEN (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,426

(22) Filed: Nov. 10, 2004

(30) Foreign Application Priority Data
Apr. 30, 2004 (TW) 93112147

(51) Int. Cl. H05K 1/16; H05K 1/11; H05K 1/14

(52) U.S. Cl. 174/260

(57) ABSTRACT

A pin grid array (PGA) package carrier is provided. The PGA package carrier is capable of mounting at least a passive component having a plurality of electrodes thereon. The PGA package carrier comprises a substrate, a plurality of passive component electrode pads, a plurality of pins, and a plurality of pre-soldering blocks. The pins and the passive component electrode pads are disposed on a surface of the substrate. Furthermore, the pre-soldering blocks are disposed on the passive component electrode pads respectively. The passive component electrode pads are electrically connected to the respective electrodes of the passive component through the pre-soldering blocks respectively. The present invention enhances both the production capacity and yield of the PGA package and facilitates the mounting of surface-mounted passive components with densely packed terminals.

### CROSS-REFERENCE TO RELATED APPLICATION

This application claims the priority benefit of Taiwan application serial no. 93112147, filed on Apr. 30, 2004.

### BACKGROUND OF THE INVENTION

1. Field of the Invention

The present invention relates to a pin grid array package carrier. More particularly, the present invention relates to a pin grid array package carrier with a surface mount technology (SMT) passive component thereon.

2. Description of Related Art

With the rapid development of electronic technologies, more personalized, multi-functional and high-tech products are produced. Furthermore, these electronic products often have a light and compact body to increase the portability. In circuit layout, a circuit carrier is a common means of mounting components. Circuit carriers such as printed circuit board (PCB) or a chip carrier mainly comprises a stack of alternately laid patterned circuit layers and dielectric layers. The dielectric layer is disposed between every pair of neighboring patterned circuit layers and the neighboring patterned circuit layers are electrically connected through a plurality of plated through holes (PTH) or vias through the dielectric layer. Because a circuit carrier has a dense circuit layout, compact assembly and good electrical performance, it has been widely adopted as a package carrier of an electrical package.

Electrical packages operating at a high frequency often produce considerable noise as a result of inductance or voltage drop. Conventionally, to reduce noise and maintain a high transmission quality, at least one de-coupling capacitor is disposed on the circuit carrier of the electrical package. However, for a pin grid array (PGA) package having a thin naked chip and a package carrier with high-density surface wiring, an electronic component can hardly mount on the top surface of the package carrier just like the chip. In other words, any bulky electronic component must be disposed on the bottom surface of the package carrier just like the pins.

To pack as many pins in array format on a package carrier, a plurality of through holes is formed on the package carrier. Thereafter, pins are inserted into the through holes and fixed in position by soldering. With this method, a lot of layout area is wasted. Hence, to increase the layout density of the pin grid package carrier, a surface mount technology (SMT) is conventionally used. In surface mount technology, one end of each pin is soldered to a bonding pad on the surface of the package carrier. Since the pins will not occupy any interior circuit area of the package carrier, this increases the layout density of the PGA package carrier.

To mount a passive component on the PGA package carrier, the electrodes of the passive component are soldered to a plurality of electrode pads. The process of mounting the passive component includes smearing a layer of solder paste on the electrode pads and aligning the various electrodes of the passive component with the solder paste. After performing a reflow process, the solder material will bond the electrodes and corresponding electrode pads together. It should be noted that a plurality of pins might have already formed on the surface of the PGA package carrier for mounting a passive component before mounting the passive component. Therefore, if a solder printing method is used to form the solder paste on the electrode pads, the pins may interfere with and prevent a proper positioning of the mask or stencil over the PGA package carrier. In other words, the solder printing method cannot be used to apply solder paste on the electrode pads before mounting a passive component on a PGA package carrier. An alternative method of putting solder paste on the electrode pads is the so-called solder dotting method, in which solder paste is disposed on the electrode pads one at a time. In the following, the solder dotting method for mounting a passive component on a PGA package carrier is described in more detail.

FIGS. 1A through 1D are schematic cross-sectional views showing the conventional process of mounting a passive component on a pin grid array package carrier. First, as shown in FIG. 1A, a pin grid array (PGA) package carrier 100 is provided. The PGA package carrier 100 is suitable for forming a pin grid array (PGA) package. Here, a pin grid array package carrier 100 having a plurality of surface-mounted pins thereon is used as an example. The PGA package carrier 100 comprises a substrate 110, a plurality of pin pads 120 (only one is shown), a plurality of passive component electrode pads 130, a solder mask 140 and a plurality of pins 150 (only one is shown). The pin pads 120 and the passive component electrode pads 130 are disposed on an upper surface 112 of the substrate 110. The solder mask 140 covers the surface 112 of the substrate 110 but has a plurality of openings 140a and 140b that expose the pin pads 120 and the passive component electrode pads 130 respectively. The pins 150 are disposed on the pin pads 120 so that the PGA package carrier 100 may electrically connect with a printed circuit board (not shown) through a socket.

As shown in FIG. 1B, solder paste 160 is disposed on each passive component electrode pad 130 one by one using a solder dotting method. The solder paste 160 comprises some solder powder mixed with an adhesive glue or flux. As shown in FIG. 1C, the electrodes 170a, 170b of a passive component 170 are joined to the passive component electrode pads 130 through the solder paste 160. As shown in FIG. 1D, a reflow process is carried out to melt the solder paste 160 and join the electrodes 170a, 170b to the passive component electrode pads 130 through the solder inside the solder paste 160.

It should be noted that the solder paste 160 is disposed on the passive component electrode pads 130 one by one using a solder dotting method. Since a longer time is required to complete the dotting process, the production throughput of the electrical package will drop. In addition, it is difficult to control the size of each drop of solder paste 160 deposited on the passive component electrode pad 130 in the dotting process. If two neighboring solder paste drops are too large, a solder bridge may form leading to a short circuit between neighboring passive component electrode pads 130 or too much residual paste may accumulate on the surface of the substrate 110 leading to a messy appearance. Although high precision dotting equipment can be use to deposit solder paste on high-density contacts surface-mounted components such as passive components with low parasitic inductance (ESL) or low parasitic resistance (ESR), productivity of the electrical package can hardly improve.

### SUMMARY OF THE INVENTION

Accordingly, the present invention is directed to a pin grid array (PGA) package carrier and process of mounting a passive component thereon capable of increasing the production rate and yield of PGA packages.

According to an embodiment of the present invention, a pin grid array (PGA) package carrier capable of mounting at least a passive component having a plurality of electrodes is provided. The PGA package carrier at least comprises a substrate, a plurality of pins, a plurality of passive component electrode pads and a plurality of pre-soldering blocks. The substrate has a surface. The pins and the passive component electrode pads are disposed on the surface of the substrate. The pre-soldering blocks are disposed on various passive component electrode pads. Each passive component electrode pad is electrically connected to a corresponding electrode of the passive component.

The present invention is also directed to a process of mounting a passive component comprising at least three steps. First, a pin grid array (PGA) package carrier comprising at least a substrate, a plurality of pins, a plurality of passive component electrode pads and a plurality of pre-soldering blocks, is provided. The substrate has a surface. The pins and the passive component electrode pads are disposed on the surface of the substrate. The pre-soldering blocks are disposed on various passive component electrode pads. Thereafter, the electrodes of the passive component are disposed on corresponding pre-soldering blocks. A reflow process is carried out so that the passive component electrode pads are electrically connected to the electrodes of at least one passive component through the pre-soldering blocks.

In the present invention, a plurality of pre-soldering blocks is accurately disposed on the passive component electrode pads of a PGA package carrier. Therefore, the electrodes of a passive component can easily align with various pre-soldering blocks and perform a reflow process to connect the electrodes and the passive component electrode pads together through various pre-soldering blocks. As a result, the present invention is not only able to increase the production rate of the PGA package, but also to provide a better control of the bulk of each pre-soldering block. Hence, solder bridging and residual solder material problems that might cause a drop in the yield are minimized.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing the conventional process of mounting a passive component on a pin grid array package carrier.

FIGS. 2A through 2D are schematic cross-sectional views showing the process of mounting a passive component on a pin grid array package carrier according to one preferred embodiment of the present invention.

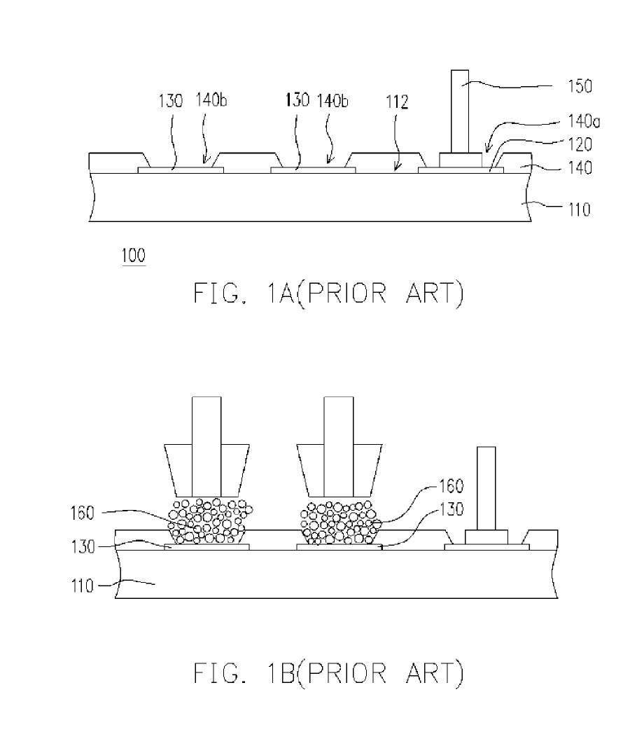

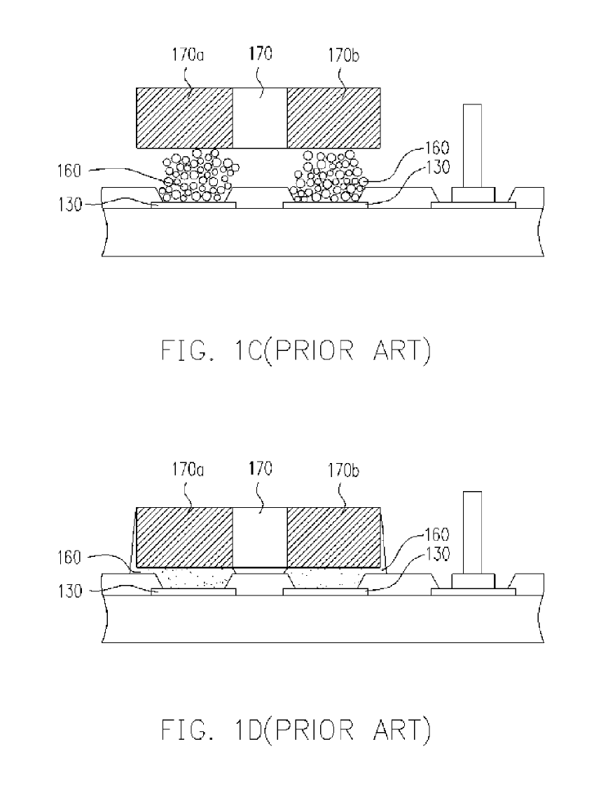

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

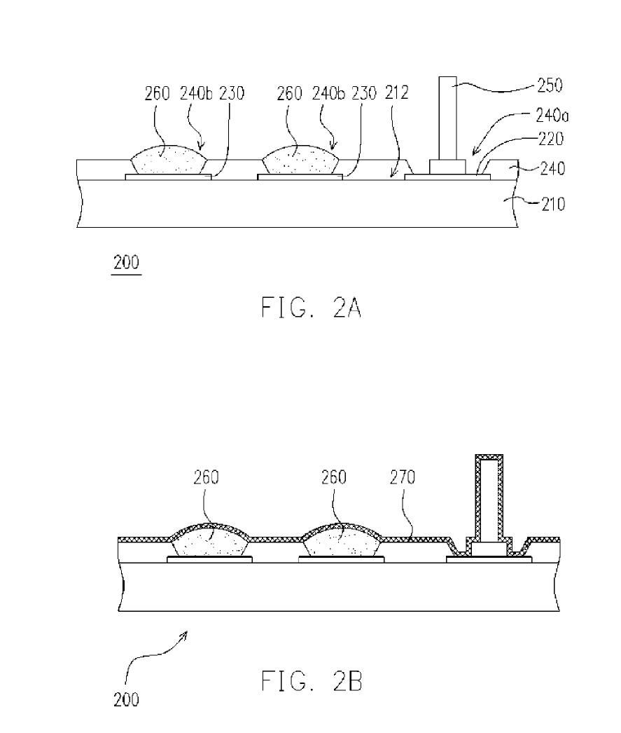

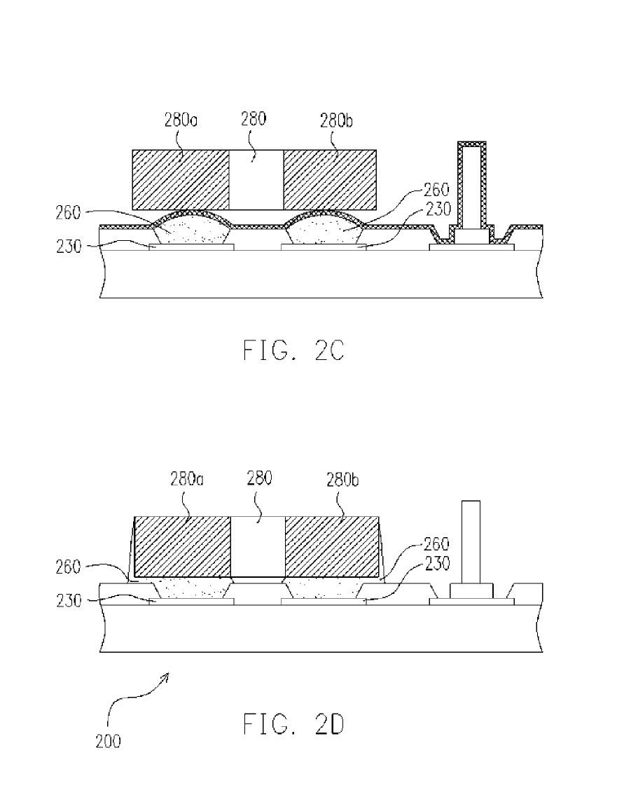

FIGS. 2A through 2D are schematic cross-sectional views showing the process of mounting a passive component on a pin grid array package carrier according to one embodiment of the present invention. First, as shown in FIG. 2A, a pin grid array (PGA) package carrier 200 is provided. The PGA package carrier 200 can be used to form a PGA package. In the present embodiment, a surface-mounted PGA package carrier 200 is used as an example. The PGA package carrier 200 comprises a substrate 210, a plurality of pin pads 220 (only one is shown), a plurality of passive component electrode pads 230, a solder mask 240, a plurality of pins 250 (only one is shown) and a plurality of pre-soldering blocks 260. The pin pads 220 and the passive component electrode pads 230 are portions of an outermost patterned circuit layer (not shown) formed on a surface 212 of the substrate 210. Typically, the pin pads 220 and the passive component electrode pads 230 are fabricated using copper, for example.

The solder mask 240 covers the surface 212 of the substrate 210. The solder mask 240 has a plurality of openings 240a, 240b that exposes the pin pads 220 and the passive component electrode pads 230 and produces solder mask defined (SMD) junction pads. The solder mask 240 may serve as a barrier for the flow of melted pre-soldering block 260 material in a subsequent reflow process so that any bridging between neighboring pre-soldering blocks 260 leading to a short circuit between neighboring passive component electrode pads 230 is prevented.

It should be noted that the steps illustrated in FIG. 2A including the process of disposing the pins 250 and the pre-soldering blocks 260 on the pin pads 220 and the passive component electrode pads 230 respectively are completed early on in the mounting process. The pre-soldering blocks 260 are formed over the electrode pads 230 by electro-plating or printing, for example. Hence, through these pre-soldering blocks 260, at least one passive component can be mounted on the PGA package carrier 200. The passive component can be a surface mount technology (SMT) component such as a high-density terminal surface-mounted component. Furthermore, the pre-soldering blocks are fabricated using lead solder or lead-free solder, for example.

Thereafter, a dipping, a spraying or a coating process is performed to produce a flux layer 270 over the PGA package carrier 200. When the pre-soldering blocks 260 are melted in a reflow process, the flux layer 270 increases the bondability of the pre-soldering blocks 260 between the electrodes 280a, 280b and the passive component electrode pads 230. As shown in FIG. 2C, the electrodes 280a, 280b of a passive component 280 are aligned to make contact with corresponding pre-soldering blocks 260. As shown in FIG. 2D, a reflow process is carried out to melt the pre-soldering blocks 260 so that the two electrodes 280a, 280b of the passive component 280 are electrically connected to corresponding passive component electrode pads 230 through the pre-soldering blocks 260. Thus, the process of mounting a surface-mounted passive component onto the back surface of a PGA package carrier is complete. It should be noted that a cleaning process could be carried out to remove any residual flux layer (not shown) on the PGA package carrier 200.

In summary, major advantages of the passive component mounting process and the pin grid array package carrier of the present invention include:
1. Since the PGA package carrier has a plurality of pre-soldering blocks accurately disposed on the passive component electrode pads early on, there is no need to perform a solder paste dotting process. Thus, the production time for forming a PGA electrical package is shortened and overall production rate is increased.
2. With the pre-soldering blocks accurately positioned on the passive component electrode pads early on, bridging between two neighboring pre-soldering blocks during the reflux process is prevented. Because the chance of a short circuit between neighboring passive component electrode pads is reduced, yield of the electrical package is increased. Furthermore, the pre-soldering blocks produce less residual solder material on the PGA package carrier so that the surface of the PGA package carrier looks less messy.
3. Because the pre-soldering blocks are accurately positioned on the passive component electrode pads early on, density of pre-soldering blocks can be increased. Consequently, the high-density contacts of a surface-mounted component can be attached to the same side of the PGA package carrier on which the pins are laid.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A process of mounting a passive component on a pin grid array package carrier, comprising the steps of:
providing a pin grid array package carrier having:
a substrate, having a surface;
a plurality of pins, disposed on the surface of the substrate;
a plurality of passive component electrode pads, disposed on the surface of the substrate; and
a plurality of pre-soldering blocks, disposed on the passive component electrode pads respectively;
positioning a plurality of electrodes of a passive component on the pre-soldering blocks respectively; and
performing a reflow process so that the passive component electrode pads are electrically connected to the electrodes of the passive component through the pre-soldering blocks.

2. The process of claim 1, wherein the pin grid array package carrier further comprises a solder mask that covers the substrate surface but exposes the pins and at least a portion of each the passive component electrode pad.

3. The process of claim 1, wherein after the step of providing the pin grid array package carrier, further comprises a step of forming a flux layer over the pin grid array package carrier.

4. The process of claim 3, wherein the step of forming a flux layer over the pin grid array package carrier comprises dipping the pin grid array package carrier in a pool of flux material.

5. The process of claim 3, wherein the step of forming a flux layer over the pin grid array package carrier comprises spraying flux material over the pin grid array package carrier.

6. The process of claim 3, wherein the step of forming a flux layer over the pin grid array package carrier comprises coating flux material over the pin grid array package carrier.

7. The process of claim 3, wherein after performing the reflow process, further comprises a step of performing a residual flux material cleaning process.

8. The process of claim 1, wherein the step of providing a pin grid array package carrier further comprises a step of disposing the pre-soldering blocks over the passive component electrode pads in an electro-plating or a printing process.

9. A pin grid array package carrier suitable for mounting at least a passive component with a plurality of electrodes thereon, comprising:
a substrate, having a surface;
a plurality of pins, disposed on the surface of the substrate;
a plurality of passive component electrode pads, disposed on the surface of the substrate; and
a plurality of pre-soldering blocks, disposed on the passive component electrode pads respectively, wherein the passive component electrode pads are electrically connected to the electrodes of the passive component through the pre-soldering blocks respectively.

10. The PGA package carrier of claim 9, wherein the carrier further comprises a plurality of pin pads disposed on the surface of the substrate.

11. The PGA package carrier of claim 9, wherein the carrier further comprises a solder mask that covers the substrate surface but exposes the pin pads and at least a portion of each the passive component electrode pad.

12. The PGA package carrier of claim 10, wherein material constituting the pin pads comprises copper.

13. The PGA package carrier of claim 9, wherein the PGA package carrier comprises an IC package substrate.

14. The PGA package carrier of claim 9, wherein material constituting the pre-soldering blocks comprises lead solder or lead-free solder.

15. The PGA package carrier of claim 9, wherein material constituting the passive component electrode pads comprises copper.

16. The PGA package carrier of claim 9, wherein the passive component comprises a surface-mounted component.
